(19) United States
(12) Patent Application Publication
(10) Pub. No.: US 2016/0086879 A1
(43) Pub. Date: Mar. 24, 2016

(54) PACKAGE SUBSTRATE AND METHOD OF FABRICATING THE SAME

(71) Applicant: Siliconware Precision Industries Co., Ltd., Taichung (TW)

(72) Inventors: Ming-Chen Sun, Taichung (TW); Chun-Hsien Lin, Taichung (TW); Tzu-Chieh Shen, Taichung (TW); Shih-Chao Chiu, Taichung (TW); Yu-Cheng Pai, Taichung (TW)

(21) Appl. No.: 14/805,524

(22) Filed: Jul. 22, 2015

(30) Foreign Application Priority Data
Sep. 18, 2014 (TW) 103123328

(51) Int. Cl. H01L 23/498; H01L 21/48

(52) U.S. Cl. CPC H01L 23/49827; H01L 23/49822; H01L 23/49838; H01L 21/4857; H01L 21/486

(57) ABSTRACT

A package substrate includes a substrate body having a first surface and a second surface opposite to the first surface; a first circuit layer formed on the first surface and having first conductive pads; a first dielectric layer formed on the first surface and the first circuit; a second circuit layer formed on the first dielectric layer and having second conductive pads; a third circuit layer formed on the second surface and having third conductive pads; a second dielectric layer formed on the second surface and the third circuit layer; a fourth circuit layer formed on the second dielectric layer and having fourth conductive pads; through holes penetrating through the first and second surfaces, and the first and second dielectric layers; and conductive vias penetrating through the through holes and electrically connected to the first, second, third and fourth conductive pads.

### BACKGROUND OF THE INVENTION

1. Field of the Invention

The present invention relates to package substrates and methods of fabricating the same, and, more particularly, to a package substrate formed with through holes by laser ablation and methods of fabricating the same.

2. Description of Related Art

With increasing demand on functionalities of electronic products, demand of package fabricating technology raises together, bringing about a variety of such technologies.

FIG. 1 illustrates a schematic cross-sectional view of a conventional package substrate 1, which has four circuit layers, for example. The package substrate 1 includes a substrate body 10, a first circuit layer 11, a first dielectric layer 13, a second circuit layer 12, a fourth circuit layer 15, a second circuit layer 16, a third circuit layer 14, conductive through holes 18, and conductive vias 19.

The substrate body 10 has a first surface 10a and a second surface 10b opposite to the first surface 10a, and can be made of glass fibers. The first circuit layer 11 is formed on the first surface 10a, and has first conductive pads 111. The first dielectric layer 13 is formed on the first surface 10a and the first circuit layer 11. The second circuit layer 12 is formed on the first dielectric layer 13, and has second conductive pads 121. The third circuit layer 14 is formed on the second surface 10b, and has third conductive pads 141. The second dielectric layer 16 is formed on the second surface 10b and third circuit layer 14. The fourth circuit layer 15 is formed on the second dielectric layer 16, and has fourth conductive pads 151. A first insulation layer 30 can be formed on the first dielectric layer 13, if necessary, and has first openings 301 for exposing the second conductive pads 121. A conductive element 32 such as a solder ball can be formed on each of the second conductive pads 121 in the first openings 301. A second insulation layer 31 can be formed on the second dielectric layer 16, if necessary, and has second openings 311 for exposing the fourth conductive pad 151. A conductive element 32 such as a solder ball can be formed on each of the fourth conductive pads 151 in the second openings 311.

The conductive through holes 18 and the conductive vias 19 are formed by forming vias (not illustrated) in the substrate body 10, the first dielectric layer 13, and the second dielectric layer 16 by laser ablation, and then filling conductive materials in the vias. However, it causes a problem of taking longer process time.

FIG. 2 illustrates a schematic cross-sectional view of another aspect of the conventional package substrate 1. The package substrate 1 depicted in FIG. 2 differs from the package substrate 1 depicted in FIG. 1 in that the package substrate 1 depicted in FIG. 2 is formed with a mere conductive through hole 18 penetrating through the substrate body 10, each of the conductive pads and dielectric layers. The conductive through hole 18 is formed by drilling through the substrate body 10, each of the conductive pads, and each of the dielectric layers to form the through hole 17 which then serves the conductive through hole 18. However, a width P of the through hole 17 created by the drill is less than 100 μm, thereby causing the conductive through hole 18 to have a width greater than 100 μm. As a result, high density layout of circuits can not be met.

Furthermore, the conventional package substrate 1 are generally formed with a metal layer (not illustrated) in the substrate body 10, in order to form conductive through hole 18 in the through hole 17 by electroplating after the through hole 17 is formed. However, because the metal layer is not translucent for light, precise alignment of drilling is hard to achieve while drilling the package substrate 1 from two sides thereof (i.e., whether alignment has been achieved cannot be determined according to translucence), leading to alignment failure and subsequent electrical connection failure.

Therefore, how to overcome the above-described problems has become critical.

### SUMMARY OF THE DISCLOSURE

In view of the above-described drawbacks, the present invention provides a package substrate, comprising: a substrate body having a first surface and a second surface opposite to the first surface; a first circuit layer formed on the first surface and including a plurality of first conductive pads, each of the first conductive pads having a first opening penetrating therethrough; a first dielectric layer formed on the first surface of the substrate body and the first circuit layer; a second circuit layer formed on the first dielectric layer and having a plurality of second conductive pads; a third circuit layer formed on the second surface of the substrate body and including a plurality of third conductive pads, each of the third conductive pads having a third opening penetrating therethrough and corresponding in position to the first opening; a second dielectric layer formed on the second surface of the substrate body and the third circuit layer; a fourth circuit layer formed on the second dielectric layer and having a plurality of fourth conductive pads; a plurality of through holes penetrating the first surface and the second surface of the substrate body, the first dielectric layer, and the second dielectric layer, formed by laser ablation, and having a maximum width less than or equal to 100 μm; and a conductive via formed in the through hole, the first opening, and the third opening, electrically connected to the first conductive pad, the second conductive pad, the third conductive pad, and the fourth conductive pad, and having a maximum width less than or equal to 100 μm.

The present invention further provides a method of fabricating a package substrate, comprising: providing a substrate body having a first surface and a second surface opposite to the first surface; forming on the first surface a first circuit layer including a plurality of first conductive pads, each of the first conductive pads having a first opening penetrating therethrough; forming a first dielectric layer on the first surface and the first circuit layer; forming on the first dielectric layer a second circuit layer including a plurality of second conductive pads, each of the second conductive pads having a second opening penetrating therethrough and corresponding in position to the first opening; forming on the second surface a third circuit layer including a plurality of third conductive pads, each of the third conductive pads having a third opening penetrating therethrough and corresponding in position to the first opening; forming a second dielectric layer on the second surface and the third circuit layer; forming on the second dielectric layer a fourth circuit layer including a plurality of fourth conductive pads, each of the fourth conductive pads having a fourth opening penetrating therethrough and corresponding in position to the first opening; forming a plurality of through holes penetrating through the substrate body, the first dielectric layer, and the second dielectric layer by laser ablation, such that the first opening, the second opening, the third opening, the fourth opening, and the through hole are in communication with one another; and forming in the first opening, the second opening, the third opening, the fourth opening, and the through hole a conductive via electrically connected to the first conductive pad, the second conductive pad, the third conductive pad, and the fourth conductive pad.

The present invention further provides a method of fabricating a package substrate, comprising: providing a substrate body having a first surface and a second surface opposite to the first surface; forming on the first surface a first circuit layer including a plurality of first conductive pads, each of the first conductive pads having a first opening penetrating therethrough; forming a first dielectric layer on the first surface and the first circuit layer; forming on the second surface a third circuit layer including a plurality of third conductive pads, each of the third conductive pads having a third opening penetrating therethrough and corresponding in position to the first opening; forming a second dielectric layer on the second surface and the third circuit layer; forming a plurality of through holes penetrating the substrate body, the first dielectric layer, and the second dielectric layer by laser ablation, such that the first opening, the third opening and the through hole are in communication with one another; forming in the first opening, the third opening, and the through hole a conductive via electrically connected to the first conductive pad and the third conductive pad; and forming on the first dielectric layer a second circuit layer including a plurality of second conductive pads electrically connected to the conductive vias, and forming on the second dielectric layer a fourth circuit layer including a plurality of fourth conductive pads electrically connected to the conductive vias.

By forming the first opening, the second opening, the third opening, and the fourth opening in the first conductive pad, the second conductive pad, the third conductive pad, and the fourth conductive pad, respectively, followed by performing laser ablation to make the first opening, the second opening, the third opening, and the fourth opening communicated with each other, and then forming the conductive via in the first opening, the second opening, the third opening, the fourth opening, and the through hole, and rather than forming a metal layer in the substrate body, such that the package substrate in accordance with the present invention allows the light to pass through the substrate body. Consequently, it facilites the drilling alignment when performing laser ablation. Therefore, the invention can solve problems, such as longer process time, inability to high-density circuit layout, alignment failure and electrical connection failure, in the prior art.

### BRIEF DESCRIPTION OF THE DRAWINGS

FIG. 1 is a schematic cross-sectional view of a package substrate according to the prior art.

FIG. 2 is a schematic cross-sectional view of another aspect of a package substrate according to the prior art.

FIGS. 3A-3C are schematic cross-sectional views illustrating one aspect of a method of fabricating a package substrate according to the present invention, and FIG. 3B′ shows another aspect of a structure depicted in FIG. 3B; and

FIGS. 4A-4C are schematic cross-sectional views illustrating another aspect of a method of fabricating a package substrate according to the present invention.

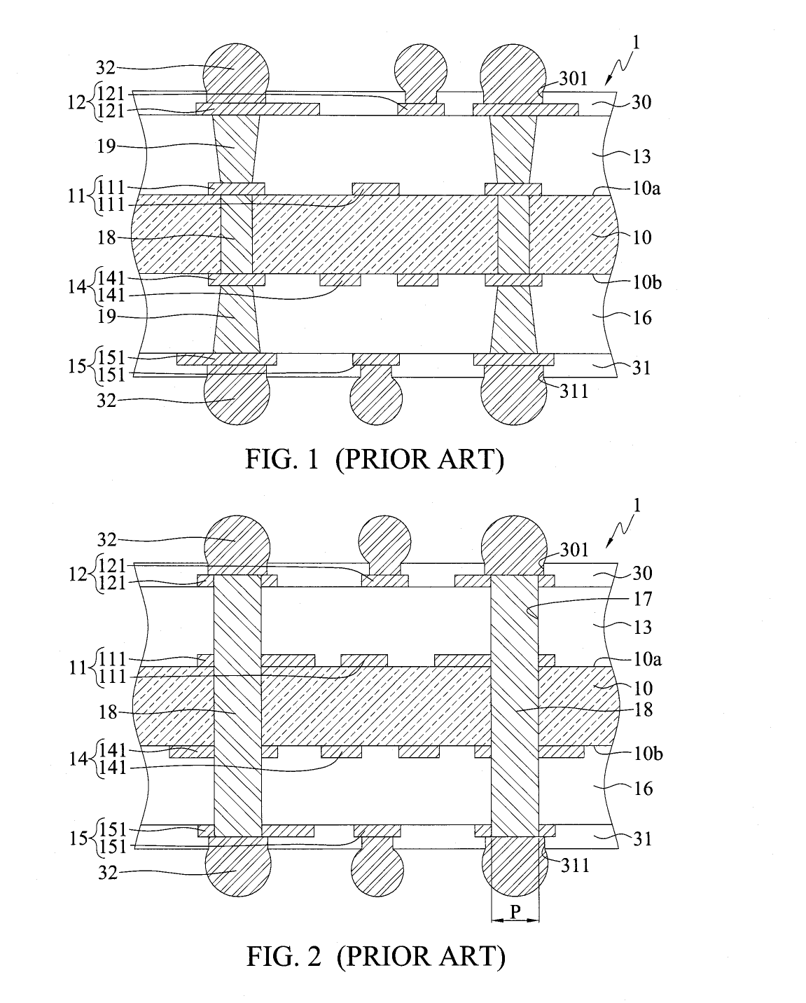

### DETAILED DESCRIPTION

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “in”, “first”, “second”, “a”, “an” etc. are merely for illustrative purposes and should not be construed to limit the scope of the present invention.

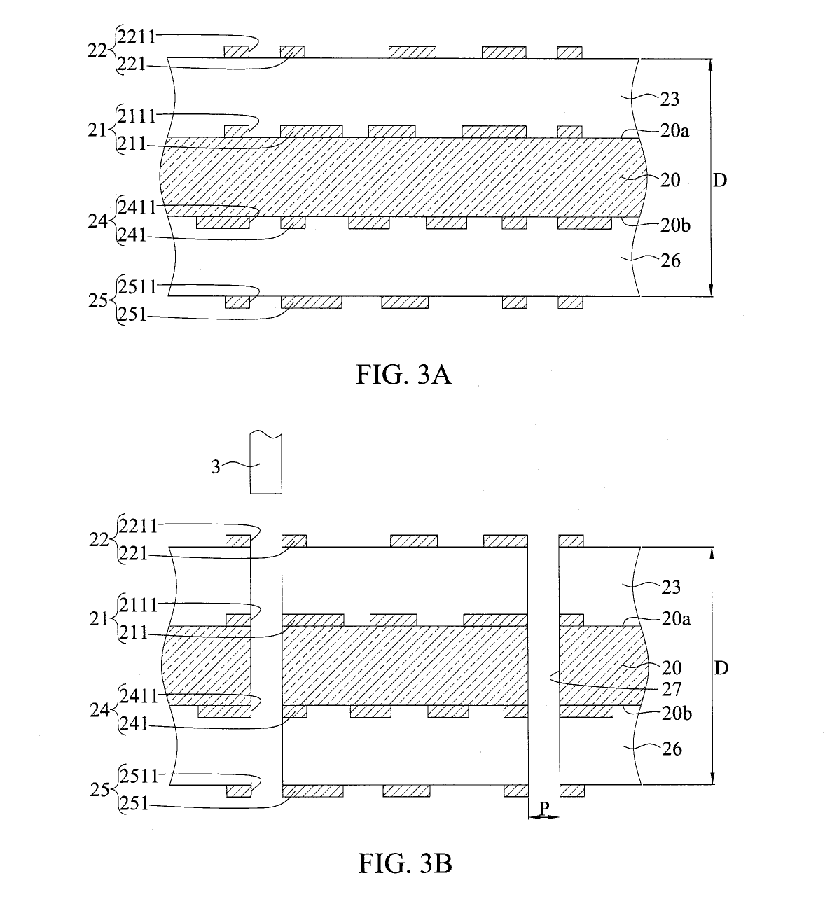

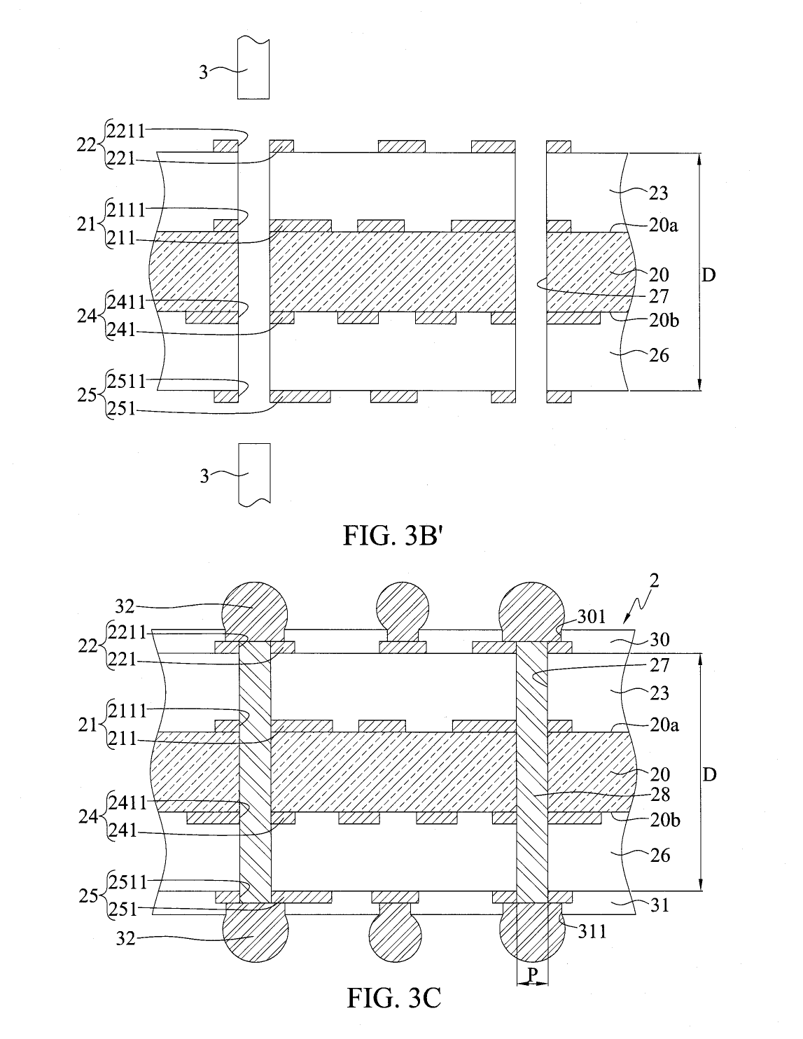

FIGS. 3A-3C are schematic cross-sectional views illustrating a method of fabricating a package substrate according to one aspect of the present invention. For example, a package substrate having four circuit layers is shown in FIGS. 3A-3C.

Referring to in FIG. 3A, a substrate body 20 having a first surface 20a and a second surface 20b opposite to the first surface 20a is provided. In an embodiment, the substrate body 20 is made of glass fiber. A first circuit layer 21 including a plurality of first conductive pads 211 is formed on the first surface 20a, and each of the first conductive pads 211 has a first opening 2111 penetrating therethrough. A first dielectric layer 23 is formed on the first surface 20a and the first circuit layer 21. A second circuit layer 22 including a plurality of second conductive pads 211 is formed on the first dielectric layer 23, and each of the second conductive pads 221 has a second opening 2211 penetrating therethrough and is positioned corresponding to the first opening 2111. A third circuit layer 24 including a plurality of third conductive pads 241 is formed on the second surface 20b, and each of the third conductive pads 241 has a third opening 2411 is positioned corresponding to the first opening 2111 and penetrating through the third conductive pad 241. A second dielectric layer 26 is formed on the second surface 20b and the third circuit layer 24. A fourth circuit layer 25 including a plurality of fourth conductive pads 251 is formed on the second dielectric layer 26, and each of the fourth conductive pads 251 has a fourth opening 2511 positioned corresponding to the first opening 2111 and penetrating therethrough. In another embodiment, the package substrate may have more than four circuit layers. That is to say, other dielectric layers and circuit layers can be formed on the first dielectric layer 23 or the second dielectric layer 26. Detailed description thereof is omitted hereafter.

Referring to FIG. 3B, the package substrate has a thickness D less than 100 μm. By performing laser ablation on the first dielectric layer 23 to ablaze the first dielectric layer 23, the substrate body 20, and the second dielectric layer 26 sequentially using the laser 3, a through hole 27 can be formed to penetrate through the first dielectric layer 23, the substrate body 20, and the second dielectric layer 26, such that the first opening 2111, the second opening 2211, the through hole 27, the third opening 2411, and the fourth opening 2511 are in communication with one another. In an embodiment, the through hole 27 has a maximum width P less than or equal to 100 μm.

Because the first opening 2111, the second opening 2211, the third opening 2411, and the fourth opening 2511 are formed in the first conductive pad 211, the second conductive pad 221, the third conductive pad 241, and the fourth conductive pad 251, respectively, and in a case that the thickness D of the package substrate is less than 100 μm and a distance by laser ablation of the laser 3 is less than or equal to 100 μm, the laser 3 can penetrate through the second opening 2211, the first opening 2111, the third opening 2411, and the fourth opening 2511 so as to ablate the first dielectric layer 23, the substrate body 20, and the second dielectric layer 26, such that the through hole 27 is formed, without being obstructed by the metal layer in the substrate body in the prior art.

Therefore, in the present invention the through hole 27 is formed by laser ablation to communicate with the first opening 2111, the second opening 2211, the third opening 2411, and the fourth opening 2511, thereby avoiding time from being spent on forming through holes or vias in each layer and inability to high-density circuit layout due to over-sized holes formed by machines.

FIG. 3B′ is a schematic cross-sectional view of another aspect of a structure shown in FIG. 3B. Referring to FIG. 3B′, there is no metal layer formed in the substrate body 20. In a case, the thickness D of the package substrate 20 is between 100 μm and 200 μm, and the distance by laser ablation of the laser 3 is less than or equal to 100 μm. In an embodiment, a first portion of the through hole 27 can be formed in advance by performing laser ablation on the first dielectric layer 23, and a second portion of the through hole 27 can then be formed by performing laser ablation on the second dielectric layer 26. Whether the first portion and the second portion of the through hole 27 are aligned with each other or not can be determined by intensity difference of the light pass it through the portion of the second dielectric layer 26 formed with the part of the through hole 27 and that passing through another portion of the second dielectric layer 26 the formation of the through hole 27. In other words, because there is no metal layer formed in the substrate body 20, an alignment can be arrived at when performing laser ablation on the dielectric layer 26 by observing intensity of the light pass it through the dielectric layer 26, without being obstructed by the metal layer.

On the contrary, in the prior art, since the substrate body has a metal layer, it is difficult to determine where the through hole is formed in the second dielectric layer by observing the intensity of the light pass through the dielectric layer when performing the laser ablation on the dielectric layer, thereby alignment failure arises. Such a failure leaves the first opening, the second opening, the third opening, the fourth opening, and the through hole are not communicated with each other, which further leads to problems of failures in electrical connections.

Furthermore, as shown in FIG. 3C, a conductive via 28 is formed in the first opening 2111, the second opening 2211, the third opening 2411, the fourth opening 2511 and the through hole 27 and electrically connected to the first conductive pad 211, the second conductive pad 221, the third conductive pad 241, and the fourth conductive pad 251. In an embodiment, the conductive via 28 has a maximum width less than or equal to 100 μm. Furthermore, a first insulation layer 30 can be formed on the first dielectric layer 23, if necessary, and has a plurality of openings 301 for exposing the second conductive pads 221. A conductive element 32 such as a solder ball can be formed on the second conductive pad 221 or the conductive via 28 in the opening 301 of the first insulation layer 30. A second insulation layer 31 can be formed on the second dielectric layer 26, if necessary, and has a plurality of openings 311 for exposing the fourth conductive pads 251. A conductive element 32 such as a solder ball can be formed on the fourth conductive pad 251 or the conductive via 28 in the opening 311 of the second insulation layer 31.

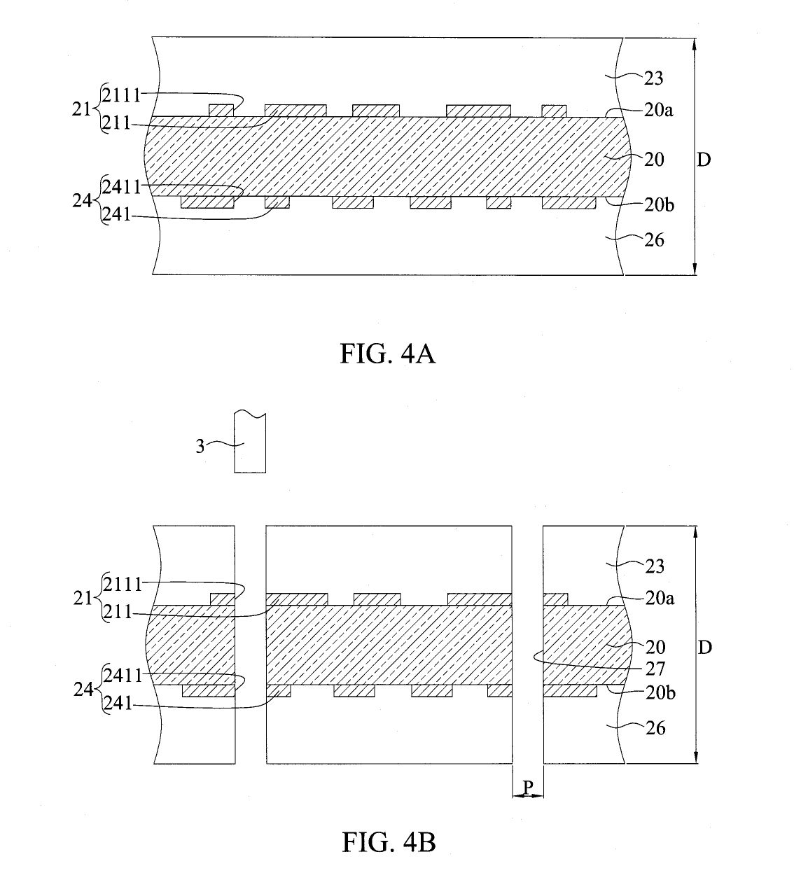

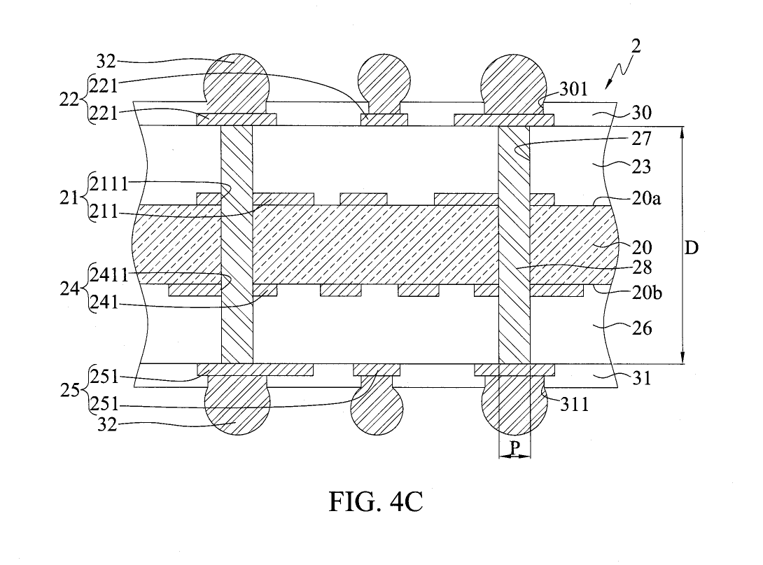

FIGS. 4A-4C are cross-sectional views illustrating a method of fabricating a package substrate according to another aspect of the present invention. For the sake of convenience, the package substrate is locally shown in FIGS. 4A-4C.

As shown in FIG. 4A, a structure depicted in FIG. 4A differs from that depicted in FIG. 3A in that there is no second circuit layer 22 formed on the first dielectric layer 23 and no fourth circuit layer 25 formed on the second dielectric layer 26.

Moreover, as shown in FIG. 4B, a structure depicted in FIG. 4B differs from that depicted in FIG. 3B in that the through hole 27 formed by laser ablation is not communicated with the second opening 2211 and the fourth opening 2511.

Furthermore, as shown in FIG. 4C, a structure depicted in FIG. 4C differs from that depicted in FIG. 3C in that the conductive via 28 is formed only in first opening 2111, the third opening 2411, and the through hole 27 and electrically connected to the first conductive pad 211 and the third conductive pad 241. After the conductive vias 28 are formed, a second circuit layer 22 is formed on the first dielectric layer 23, and the fourth circuit layer 25 is formed on the second dielectric layer 26, such that the conductive vias 28 are covered by and electrically connected to the second conductive pad 221 and fourth conductive pad 251. Hence, the package substrate 2 is completed.

Referring to FIG. 3C, a package substrate 2 is provided according to the present invention. The package substrate 2 has a substrate body 20 having a first surface 20a and a second surface 20b opposite to the first surface 20a; a first circuit layer 21 formed on the first surface 20a and including a plurality of first conductive pads 211, each of the first conductive pads 211 having a first opening 2111 penetrating therethrough; a first dielectric layer 23 formed on the first surface 20a and the first circuit 21; a second circuit layer 22 formed on the first dielectric layer 23 and having a plurality of second conductive pads 221; a third circuit layer 24 formed on the second surface 20b and including a plurality of third conductive pads 241, each of the third conductive pad 241 having a third opening 2411 penetrating therethrough and corresponding in position to the first opening 2111; a second dielectric layer 26 formed on the second surface 20b and the third circuit layer 24; a fourth circuit layer 25 formed on the second dielectric layer 26 and having a plurality of fourth conductive pads 2511; a plurality of through holes 27 formed to penetrate the first surface 20a and the second surface 20b of the substrate body 20, the first dielectric layer 23, and the second dielectric layer 26 by laser ablation, wherein a maximum width of the through hole 27 is less than or equal to 100 μm; and a conductive via 28 formed to penetrate the through hole 27, the first opening 2111, and the third opening 2411 and be electrically connected to the first conductive pad 211, the second conductive pad 221, the third conductive pad 241, and the fourth conductive pad 251, wherein a maximum width of the conductive via 28 is less than or equal to 100 μm. A thickness of the package substrate 2 can be less than or equal to 200 μm, more particularly, less than or equal to 100 μm.

In the package substrate 2 shown in FIGS. 3A-3C, the second conductive pad 211 can have a second opening 2211 positioned corresponding to the first opening 2111 and penetrating therethrough. The fourth conductive pad 251 can have a fourth opening 2511 positioned corresponding to the first opening 2111 and penetrating therethrough. The conductive via 28 is formed to extend into the second opening 2211 and the fourth opening 2511 and be electrically connected the second conductive pad 221 and the fourth conductive pad 251.

Moreover, a first insulation layer 30 can be formed on the first dielectric layer 23, if necessary, and has an opening 301 for exposing the second conductive pads 221. A conductive element 32 such as a solder ball 32 can be formed on the second conductive pad 221 or the conductive via 28 in the opening 301 of the first insulation layer 30. A second insulation layer 31 can be formed on the second dielectric layer 26, if necessary, and can have openings 311 for exposing the fourth conductive pads 251. A conductive element 32 such as a solder ball can be formed on the fourth conductive pad 251 or the conductive via 28 in the opening 311 of the second insulation layer 31.

Referring to FIG. 4C, a package substrate is provided according to another aspect of the present invention. As shown in FIG. 4C, a structure depicted in FIG. 4C differs from that depicted in FIG. 3C in that the conductive via 28 is formed only in the first opening 2111, the third opening 2411, and the through hole 27 for electrically connecting to the first conductive pad 211 and the third conductive pad 241, and that the second conductive pad 221 and the fourth conductive pad 251 do not have the second opening 2211 and the fourth opening 2511, respectively, and that the conductive via 28 is covered by and electrically connected to the second conductive pad 221 and fourth conductive pad 251. Moreover, the conductive element 32 can be formed on the second conductive pad 221 in the opening 301 of the first insulation layer 30 and on the fourth conductive pad 251 in the opening 311 of the second insulation layer 31.

In conclusion, as compared to the prior arts, because the first opening, the second opening, the third opening, and the fourth opening disclosed in the present invention are formed in first conductive pad, the second conductive pad, the third conductive pad, and the fourth conductive pad, respectively, in a case that the distance by laser ablation with a laser is less than or equal to 100 μm and the thickness of the package substrate is less than 100 μm, the laser can penetrate the substrate body, the first dielectric layer, the second dielectric layer by the first opening, the second opening, the third opening, and the fourth opening, without being obstructed by the metal layers of the electrical connecting pads in the prior arts. Therefore, by performing laser ablation once or twice to form the through hole that communicates with the first opening, the second opening, the third opening, and the fourth opening, the present invention dispenses with waste of process time on forming conductive vias in each of the dielectric layer in the package substrate as is the case in prior arts. Also can be prevented by the present invention is the problem for high-density circuit layout prohibited by over-sized holes drilled by machines.

Furthermore, in a case that the thickness of the package substrate is between 100 μm and 200 μm, because no metal layer is formed inside the substrate body in the present invention, the difference of the intensity of the light pass through the second dielectric layer where a portion with a through hole and another portions without a through hole can be observed, which allows the alignment during performing second laser ablation on the second dielectric layer, thereby avoiding the problems of alignment failures by performing a two-step laser ablation on the substrate body having a metal layer and the subsequent failures in electrical connections in the prior art.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A package substrate, comprising:
a substrate body having a first surface and a second surface opposite to the first surface;
a first circuit layer formed on the first surface and having a plurality of first conductive pads, wherein each of the first conductive pads has a first opening penetrating therethrough;
a first dielectric layer formed on the first surface of the substrate body and the first circuit layer;
a second circuit layer formed on the first dielectric layer and having a plurality of second conductive pads;
a third circuit layer formed on the second surface of the substrate body and having a plurality of third conductive pads, wherein each of the third conductive pads has a third opening penetrating therethrough and corresponding in position to the first opening;
a second dielectric layer formed on the second surface of the substrate body and the third circuit layer;
a fourth circuit layer formed on the second dielectric layer and having a plurality of fourth conductive pads;
a plurality of through holes penetrating the substrate body through the first surface and the second surface thereof, the first dielectric layer, and the second dielectric layer, formed by laser ablation, and each having a maximum width less than or equal to 100 μm; and
a plurality of conductive vias each penetrating through a corresponding one of each of the through holes, the first openings, and the third openings, electrically connected to a corresponding one of each of the first conductive pads, the second conductive pads, the third conductive pads, and the fourth conductive pads, and having a maximum width less than or equal to 100 μm.

2. The package substrate of claim 1, wherein the second conductive pad has a second opening penetrating therethrough and being positioned with respect to the first opening, the fourth conductive pad has a fourth opening penetrating therethrough and being positioned with respect to the first opening, and the conductive via extends to the second opening and the fourth opening and electrically connected to the second conductive pad and the fourth conductive pad.

3. The package substrate of claim 1, wherein the package substrate has a thickness less than or equal to 200 μm.

4. The package substrate of claim 1, wherein the package substrate has a thickness less than or equal to 100 μm.

5. A method of fabricating a package substrate, comprising:
providing a substrate body having a first surface and a second surface opposite to the first surface;
forming on the first surface a first circuit layer having a plurality of first conductive pads, wherein each of the first conductive pads has a first opening penetrating therethrough;
forming a first dielectric layer on the first surface of the substrate body and the first circuit layer;
forming on the first dielectric layer a second circuit layer having a plurality of second conductive pads, wherein each of the second conductive pads has a second opening penetrating therethrough and being corresponding in position to the first opening;
forming on the second surface a third circuit layer having a plurality of third conductive pads, wherein each of the third conductive pads has a third opening penetrating therethrough and being corresponding in position to the first opening;
forming a second dielectric layer on the second surface of the substrate body and the third circuit layer;
forming on the second dielectric layer a fourth circuit layer having a plurality of fourth conductive pads, wherein each of the fourth conductive pads has a fourth opening penetrating therethrough and being corresponding in position to the first opening;
forming a plurality of through holes penetrating through the substrate body, the first dielectric layer, and the second dielectric layer by laser ablation, such that the first opening, the second opening, the third opening, the fourth opening, and the through hole are in communication with one another; and
forming in the first opening, the second opening, the third opening, the fourth opening, and the through hole a conductive via electrically connected to the first conductive pad, the second conductive pad, the third conductive pad, and the fourth conductive pad.

6. The method of claim 5, wherein the conductive via has a maximum width less than or equal to 100 μm.

7. The method of claim 5, wherein the package substrate has a thickness between 100 μm to 200 μm.

8. A method of fabricating a package substrate, comprising:
providing a substrate body having a first surface and a second surface opposite to the first surface;
forming on the first surface a first circuit layer having a plurality of first conductive pads, wherein each of the first conductive pads has a first opening penetrating therethrough;
forming a first dielectric layer on the first surface of the substrate body and the first circuit layer;
forming on the second surface a third circuit layer having a plurality of a third conductive pads, wherein each of the third conductive pads has a third opening penetrating therethrough and being corresponding in position to the first opening;
forming a second dielectric layer on the second surface and the third circuit layer;
forming a plurality of through holes penetrating through the substrate body, the first dielectric layer, and the second dielectric layer by laser ablation, such that the first opening, the third opening and the through hole are in communication with one another;
forming in the first opening, the third opening, and the through hole a conductive via electrically connected to the first conductive pad and the third conductive pad; and
forming on the first dielectric layer a second circuit layer having a plurality of second conductive pads electrically connected to the conductive vias, and forming on the second dielectric layer a fourth circuit layer having a plurality of fourth conductive pads electrically connected to the conductive vias.

9. A method of claim 8, wherein the conductive via has a maximum width less than or equal to 100 μm.

10. A method of claim 8, wherein the package substrate has a thickness between 100 μm to 200 μm.
